(19) United States
(12) Patent Application Publication
(10) Pub. No.: US 2025/0051903 A1
(43) Pub. Date: Feb. 13, 2025

(54) VAPOR DEPOSITION MASK AND METHOD OF MANUFACTURING ORGANIC ELECTROLUMINESCENT ELEMENT BY USING VAPOR DEPOSITION MASK

(71) Applicant: CANON KABUSHIKI KAISHA, Tokyo (JP)

(72) Inventors: MASUMI ITABASHI, Kanagawa (JP); SEIJI MASHIMO, Kanagawa (JP)

(21) Appl. No.: 18/798,543

(22) Filed: Aug. 8, 2024

(30) Foreign Application Priority Data
Aug. 8, 2023 (JP) 2023-129372

(51) Int. Cl. C23C 14/04; C23C 14/24; H10K 71/16

(52) U.S. Cl. CPC C23C 14/042; C23C 14/24; H10K 71/166

(57) ABSTRACT

A vapor deposition mask includes an opening region including a first opening and a second opening, and a third opening and a fourth opening arranged outside the opening region, wherein the first opening and the second opening are arranged along a first virtual line extending in a first direction, wherein the third opening is arranged between the first opening and a first end of the vapor deposition mask in the first direction, wherein the fourth opening is arranged between the first opening and a second end of the vapor deposition mask in a second direction orthogonal to the first direction, and wherein, in the second direction, a distance between the first opening and the first virtual line is shorter than a distance between the third opening and the first virtual line.

### BACKGROUND

### Field

The present disclosure relates to a vapor deposition mask and a method of manufacturing an organic electroluminescent (EL) element by using the vapor deposition mask.

### Description of the Related Art

An organic EL element has attracted attention as a light emitting element that can perform high-luminance light emission by low-voltage driving. The organic EL element generally has a stacked structure in which a plurality of layers, for example, a positive electrode, organic layers including a hole transport layer, a light emission layer, and an electron transport layer, and a negative electrode are stacked on a substrate. As a method of forming the stacked structure, a vacuum deposition method on a substrate by using evaporation and sublimation, and a film formation method using inkjet, spin coating, or the like is performed by dissolving an organic material in a solvent.

In a case where a layer is formed using a low molecular weight material, a vacuum deposition method using a vapor deposition mask that includes an opening corresponding to a desired pattern is generally used. In the vacuum deposition method, to form the desired pattern on a substrate, film formation is performed while the vapor deposition mask including a pixel opening corresponding to the desired pattern is placed between the substrate and a heating portion of a vapor deposition material.

By cutting off the substrate on which organic EL elements are created, a plurality of chips each including the organic EL element can be obtained from one substrate. As a method of cutting out the organic EL elements from the substrate, for example, a blade dicing method that performs cutting while pressing a circular blade against the substrate is usable. As other methods, a laser abrasion method that processes a surface of the substrate with a laser beam, a laser stealth dicing method that condenses a laser beam into an inside of the substrate and applies external force to divide the substrate into chips, and the like are usable.

In the laser stealth dicing method, damage on the surface of the substrate is little, and intervals of the organic EL elements arranged on the substrate can be minimized in order to efficiently cut out the organic EL elements from one substrate (to obtain as many organic EL elements as possible).

In the blade dicing method and the laser abrasion method, the substrate is cut off while being abraded by a blade or the like. Accordingly, when the intervals of the organic EL elements arranged on the substrate are narrow, it is difficult to secure a cutoff blank space necessary for the blade dicing method and the laser abrasion method.

In contrast, in the laser stealth dicing method, front and rear surfaces of the substrate are not damaged, a step is performed in a dry state, and generation of machining wastes can be suppressed. Accordingly, the laser stealth dicing method is useful for cutting off the substrate to obtain the organic EL elements.

In the laser stealth dicing method, a cutoff blank space necessary for cutting off the substrate is extremely narrow, and a scribe width necessary for cutting the substrate can be reduced. Therefore, the intervals of the organic EL elements can be made narrow. The laser stealth dicing method is extremely effective as the method of dicing the substrate to efficiently obtain the organic EL elements from one substrate.

In a step of cutting out the organic EL elements from one substrate, an ineffective element region where the organic EL element having a desired size is not obtainable is generated depending on shapes and positions of the substrate and a film formation region. In the ineffective element region, it is unnecessary to deposit the material on the substrate. For this reason, it is unnecessary to provide an opening at a position of the vapor deposition mask facing the ineffective element region of the substrate during vapor deposition of the material for film formation.

However, when the opening region including the opening and the region including no opening coexist in the same plane of the vapor deposition mask facing the substrate, rigidity in the plane of the vapor deposition mask is deviated, the opening provided on the outermost periphery of the opening region is distorted, and vapor deposition blur occurs. The vapor deposition blur is film formation of the vapor deposition material within a wide range beyond a desired vapor deposition range on the substrate. This is caused by infiltration of the vapor deposition material into a gap generated when the vapor deposition mask and the substrate are caused to face each other.

Japanese Patent Application Laid-Open No. 2004-185832 discusses that, in a tension mask as a vapor deposition mask supported by application of tension, a dummy opening is provided on an outermost side of an effective opening portion in a tensile direction of the vapor deposition mask in unit of one display element. Japanese Patent Application Laid-Open No. 2004-185832 also discusses that a dummy opening is provided outside the effective opening portion for a plurality of display elements in one substrate, and a method obtained by combining them. With such a configuration, even when tensile force is applied to the vapor deposition mask, the dummy opening is largely distorted, and it is possible to suppress distortion of the effective opening. In the laser stealth dicing method, however, if the material adheres to the surface of the substrate, it is difficult to condense the laser beam into the inside of the substrate, and a portion where dicing cannot be performed may be generated.

### SUMMARY

The present disclosure is directed to a vapor deposition mask that can reduce film deposition of the vapor deposition material onto a scribe line that is a dicing position of the substrate.

According to an aspect of the present invention, a vapor deposition mask includes an opening region including a first opening and a second opening, and a third opening and a fourth opening arranged outside the opening region, wherein the first opening and the second opening are arranged along a first virtual line extending in a first direction, wherein the third opening is arranged between the first opening and a first end of the vapor deposition mask in the first direction, wherein the fourth opening is arranged between the first opening and a second end of the vapor deposition mask in a second direction orthogonal to the first direction, and wherein, in the second direction, a distance between the first opening and the first virtual line is shorter than a distance between the third opening and the first virtual line.

According to another aspect of the present invention, a method of manufacturing an organic electroluminescent (EL) element includes causing a vapor deposition mask and a substrate to face each other, aligning the substrate and the vapor deposition mask, and forming a desired vapor deposition pattern by vapor-depositing a vapor deposition material on the substrate through an opening of the vapor deposition mask, wherein the vapor deposition mask includes an opening region including a first opening and a second opening, and a third opening and a fourth opening arranged outside the opening region, wherein the first opening and the second opening are arranged along a first virtual line extending in a first direction, wherein the third opening is arranged between the first opening and a first end of the vapor deposition mask in the first direction, wherein the fourth opening is arranged between the first opening and a second end of the vapor deposition mask in a second direction orthogonal to the first direction, wherein, in the second direction, a distance between the first opening and the first virtual line is shorter than a distance between the third opening and the first virtual line, and wherein, in the aligning, a position of a scribe line on the substrate and the first virtual line of the vapor deposition mask face each other.

Further features of the present invention will become apparent from the following description of exemplary embodiments with reference to the attached drawings.

### BRIEF DESCRIPTION OF THE DRAWINGS

FIGS. 1A to 1C are schematic diagrams illustrating examples of a vapor deposition mask according to an exemplary embodiment.

FIGS. 2A to 2E are enlarged views of parts of the vapor deposition mask of any one of FIGS. 1A to 1C, for describing examples of the vapor deposition mask according to the exemplary embodiment.

FIGS. 3A to 3F are enlarged views of parts of the vapor deposition mask of any one of FIGS. 1A to 1C, illustrating for describing examples of the vapor deposition mask according to the exemplary embodiment.

FIG. 4A is a schematic diagram illustrating an example of the vapor deposition mask according to the exemplary embodiment, and FIGS. 4B and 4C are enlarged partial views of the vapor deposition mask illustrated in FIG. 4A.

FIG. 5A is a schematic diagram illustrating an example of the vapor deposition mask according to the exemplary embodiment, and FIGS. 5B and 5C are enlarged partial views of the vapor deposition mask illustrated in FIG. 5A.

FIGS. 6A to 6E are enlarged views illustrating examples of the vapor deposition mask according to the exemplary embodiment.

FIGS. 7A and 7B are enlarged views illustrating examples of the vapor deposition mask according to the exemplary embodiment.

FIGS. 8A and 8B are schematic diagrams illustrating examples of the vapor deposition mask according to the exemplary embodiment, FIGS. 8C and 8E are enlarged views illustrating examples of a part of the vapor deposition mask illustrated in FIG. 8A, and FIGS. 8D and 8F are enlarged views illustrating examples of a part of the vapor deposition mask illustrated in FIG. 8B.

FIGS. 9A, 9C, and 9E are enlarged views illustrating examples of a part of the vapor deposition mask illustrated in FIG. 8A, and FIGS. 9B, 9D, and 9F are enlarged views illustrating examples of a part of the vapor deposition mask illustrated in FIG. 8B.

FIGS. 10A to 10C are schematic diagrams illustrating a vapor deposition step according to an exemplary embodiment.

FIGS. 11A and 11B are schematic diagrams illustrating relationship of a substrate, a vapor deposition mask, and a vapor deposition source (crucible) in a vapor deposition chamber.

FIGS. 12A to 12C are schematic diagrams illustrating vapor deposition masks according to Comparative Examples 1 to 3, respectively.

### DESCRIPTION OF THE EMBODIMENTS

An exemplary embodiment is described in detail with reference to drawings. The exemplary embodiment described below does not limit the invention according to the claims. Although a plurality of features is described in the exemplary embodiment, all of the plurality of features are not necessarily essential for the invention, and the plurality of features may be optionally combined. In the accompanying drawings, the same or similar components are denoted by the same reference numerals, and repetitive description is omitted.

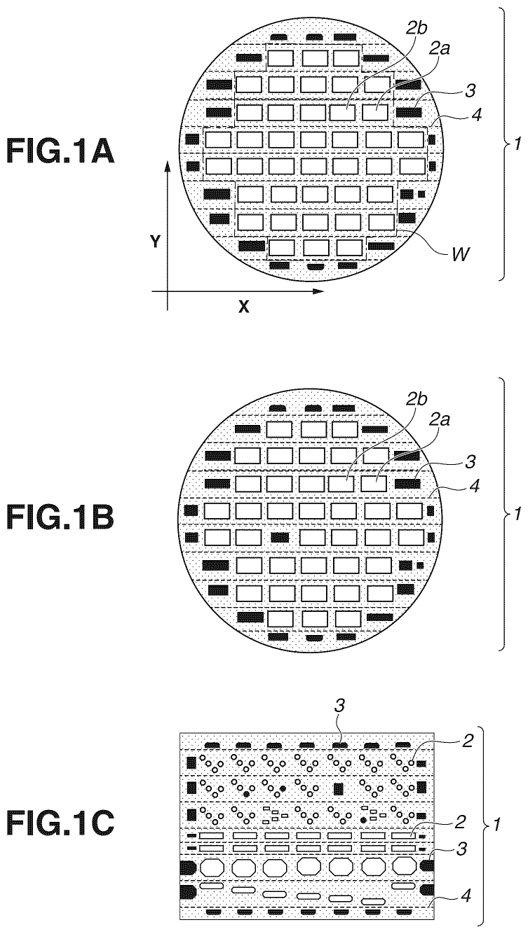

In the present exemplary embodiment, as an example of a vapor deposition mask, a vapor deposition mask used for forming a desired pattern on a substrate by a vacuum deposition method is described with reference to FIG. 1A to FIG. 12C.

A vapor deposition mask 1 according to the present exemplary embodiment can be formed using, for example, wet etching. As a material, for example, any of stainless steel, iron, copper, aluminum, silver, titanium, molybdenum, tungsten, inver, silicon, and a resin, or a combination thereof can be used, but the material is not particularly limited to these materials.

FIGS. 1A to 1C are schematic diagrams illustrating examples of the vapor deposition mask 1 according to the present exemplary embodiment. FIGS. 1A and 1B illustrate examples in which an outer shape of the vapor deposition mask 1 is a circular shape, and FIG. 1C illustrates an example in which the outer shape of the vapor deposition mask 1 is a quadrilateral shape. The vapor deposition mask 1 includes an opening region W including a plurality of effective openings 2. In the opening region W, the openings 2 as the effective openings are arranged at positions corresponding to organic electroluminescent (EL) elements formed on a substrate by vapor deposition.

The organic EL elements formed on the substrate are cut out by, for example, dicing of a laser stealth dicing method into individual organic EL element chips. In the present specification, a cutoff line of the substrate cut off in dicing is referred to as a scribe line. In the vapor deposition mask 1, a line facing the scribe line when the vapor deposition mask faces the substrate during vapor deposition, namely, a line obtained by perpendicularly projecting the scribe line to the vapor deposition mask is referred to as a virtual line.

In FIG. 1A, the opening region W includes a first opening 2a and a second opening 2b as the effective openings. The first opening 2a and the second opening 2b are arranged along a virtual line 4 (first virtual line) extending in a first direction X. Dummy openings 3 (third openings) are arranged outside the opening region W. The dummy openings 3 may be arranged, for example, on outside (on outer peripheral part side) of all openings 2 arranged in the vapor deposition mask 1, namely, at positions close to an end of the vapor deposition mask 1.

When the openings are arranged in the vapor deposition mask 1, deviation in rigidity occurs in a plane of the vapor deposition mask due to difference in structure (presence/absence of openings) between the opening region W and an outside region. Providing the dummy openings 3 between the opening region W and the end of the vapor deposition mask 1 makes it possible to relax the deviation in rigidity. For example, the third openings are disposed between the first opening 2a and the end of the vapor deposition mask 1 in the first direction X, which makes it possible to disperse force distorting the first opening 2a in the first direction, and to maintain a normal shape of the first opening 2a (or to maintain state close to normal shape).

Because deformation of the effective openings can be suppressed, it is possible to suppress vapor deposition blur when stacked films of the organic EL elements are formed on the substrate, and to realize improvement in yield in a step of manufacturing the organic EL elements and cost reduction of the organic EL elements.

The vapor deposition mask 1 illustrated in FIG. 1B is obtained by changing some of the openings 2 arranged in the opening region W in FIG. 1A to the dummy openings 3. The vapor deposition mask 1 illustrated in FIG. 1C has the quadrilateral outer shape, but the opening region W including the openings 2 as the effective openings, the dummy openings 3 arranged between the opening region W and the end of the vapor deposition mask 1, the virtual line 4, and the like are similar to those illustrated in FIGS. 1A and 1B.

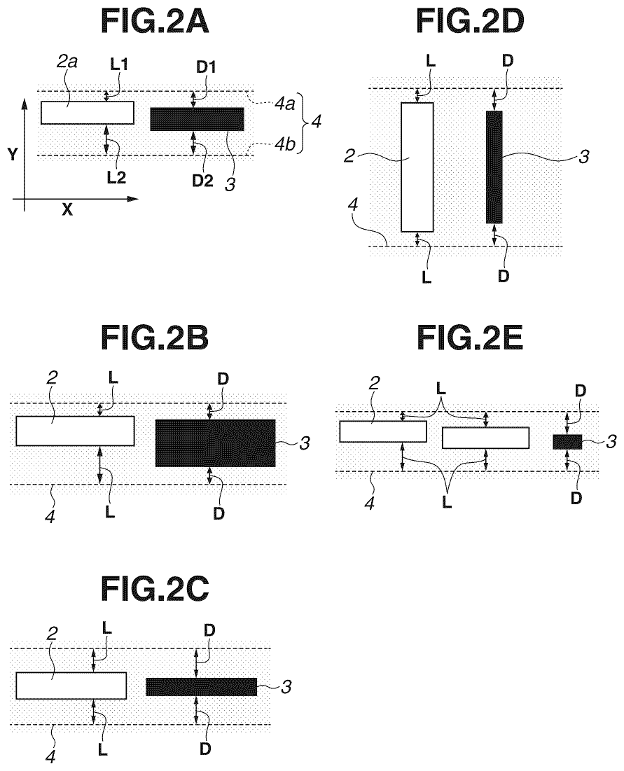

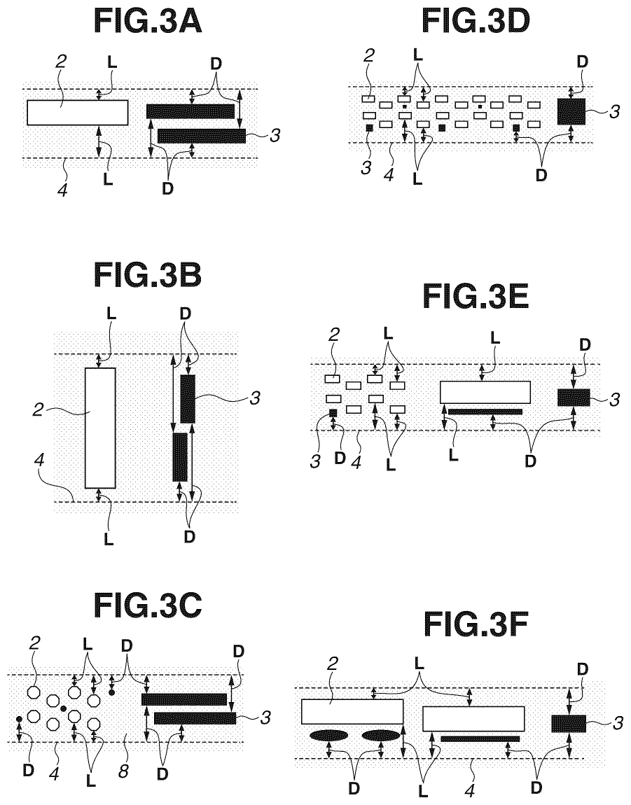

FIGS. 2A to 2E and FIGS. 3A to 3F are schematic diagrams illustrating examples of relationship between some of the openings 2 arranged in the opening region W and some of the dummy openings 3. For example, as illustrated in FIG. 2A, in the vapor deposition mask according to the present exemplary embodiment, the dummy opening 3 is arranged between the first opening 2a and the end of the vapor deposition mask 1 (on right side in drawing, not illustrated) in the first direction.

In a second direction Y orthogonal to the first direction X, a distance between the first opening 2a and a first virtual line 4a adjacent to the first opening 2a is denoted by L, and a distance between the third opening (dummy opening 3) and the first virtual line 4a is denoted by D. In the second direction Y, the distance L between the first opening 2a and the first virtual line 4a is shorter than the distance D between the third opening and the first virtual line 4a. In other words, a distance from the first virtual line 4a to the third opening is greater than a distance from the first virtual line 4a to the first opening 2a.

In the vapor deposition mask 1, the distance L between the opening 2 as the effective opening and the virtual line 4 in the second direction Y is set to a distance greater than or equal to a distance for which the vapor deposition material is not film-deposited on the scribe line even if predicted vapor deposition blur occurs in the vapor deposition step. The distance L between the first opening 2a and the first virtual line 4a being shorter than the distance D between the third opening (dummy opening 3) and the first virtual line 4a means that a distance from the first virtual line 4a to the dummy opening 3 is greater than a distance from the first virtual line 4a to the opening 2 as the effective opening. In other words, the third opening is separated in the second direction Y from the virtual line 4 by a distance greater than the distance for which the vapor deposition material is not film-deposited on the scribe line during vapor deposition.

With such a configuration, even when the shape of the dummy opening 3 is distorted, and the vapor deposition blur occurs in a range wider than a previously predicted range relative to the effective opening, it is possible to suppress adhesion (film deposition) of the vapor deposition material to the scribe line.

In the present specification, when a certain object A has an area, a distance from the object A to a line indicates a shortest distance from the object A to the line. A distance in a certain direction indicates a shortest distance between the object A and the line in the certain direction.

As a vapor deposition method using the vapor deposition mask according to the present exemplary embodiment, a rotary film formation method using a point source, a film formation method using a linear source and relatively moving a crucible and the substrate, or the like can be used. For example, in a case of the rotary film formation method, vapor deposition blur generally easily occurs as it goes from a center to outside of the substrate. This is because, in comparison between a center part and an outer peripheral part of the vapor deposition mask, even when the openings are formed with the same shape at the same cycle, the vapor deposition blur easily occurs at the outer peripheral part because an incident angle of a vapor deposition component from a vapor deposition source to each opening at the outer peripheral part is gentle.

In the film formation method using the linear source, the vapor deposition blur is generally reduced using a shielding plate in order to achieve controllability of the film formation. However, it is difficult to provide the shielding plates in all directions, and it is not possible to completely prevent film formation of the vapor deposition component on the scribe line depending on the direction.

The configuration according to the present exemplary embodiment makes it possible to suppress adhesion (film deposition) of the vapor deposition material to the scribe line due to vapor deposition blur, in the step of forming a film of the vapor deposition material by the vacuum deposition method.

In a case where a plurality of virtual lines 4 is adjacent to the first opening 2a, the shortest distance of the distances L between the first opening 2a and the plurality of virtual lines 4 in the second direction Y can be shorter than the distance D between the third opening (dummy opening 3) and the virtual line 4 in the second direction Y. For example, in FIG. 2A, a line that is adjacent to the first opening 2a on a side of the first opening 2a opposite to the first virtual line 4a and is parallel to the first virtual line 4a is referred to as a second virtual line 4b. At this time, in the second direction Y, a shorter distance of the distance between the first opening 2a and the first virtual line 4a and the distance between the first opening 2a and the second virtual line 4b can be shorter than the distance between the third opening and the second virtual line 4b.

Such a configuration makes it possible to suppress formation of the vapor deposition film on the scribe line on the substrate during vapor deposition.

The vapor deposition mask according to the present exemplary embodiment can reduce the vapor deposition blur caused by distortion of the vapor deposition mask, and can suppress film deposition on the scribe line in the vapor deposition step. This enables cutout of the organic EL elements from the substrate by, for example, the laser stealth dicing method. As a result, it is possible to realize improvement in yield in the step of manufacturing the organic EL elements and cost reduction of the organic EL elements.

In FIG. 2A, the example in which the first opening 2a has a rectangular shape including a first side parallel to the first direction X and a second side parallel to the second direction Y orthogonal to the first direction X is described, but the shape of each of the openings is not limited to the example. The openings may not have the same shape and the same size. Other examples of the opening 2 and the dummy opening 3 are described with reference to FIGS. 2B to 2E and FIGS. 3A to 3F.

FIGS. 2B and 2C illustrate examples in which the size of the dummy opening 3 is different from the size illustrated in FIG. 2A.

FIG. 2D illustrates an example in which each of the opening 2 and the dummy opening 3 has a long side parallel to the second direction Y, and a short side parallel to the first direction X. Even in such a case, in the second direction Y, the shortest distance of the distances between the first opening 2a and the virtual lines 4 is shorter than the distances between the dummy opening 3 and the virtual lines 4. Accordingly, it is possible to suppress adhesion of the vapor deposition material to the scribe line during vapor deposition while suppressing vapor deposition blur at the opening 2.

FIG. 2E illustrates an example in which the plurality of openings 2 and the dummy opening 3 are arranged in a region sandwiched by two adjacent virtual lines 4. Even in such a case, as described above, in the second direction Y, the shortest distance of the distances between the openings 2 and the virtual lines 4 can be shorter than the distances between the dummy opening 3 and the virtual lines 4.

A shorter distance of the distance between the dummy opening 3 and the first virtual line 4a and the distance between the dummy opening 3 and the second virtual line 4b can be longer than the shortest distance of the distances between the plurality of openings 2 and the first virtual line 4a. The shorter distance of the distance between the dummy opening 3 and the first virtual line 4a and the distance between the dummy opening 3 and the second virtual line 4b can be longer than the shortest distance of the distances between the plurality of openings 2 and the second virtual line 4b.

FIGS. 3A to 3F illustrate examples in which the plurality of dummy openings 3 is arranged in a region sandwiched between the two virtual lines 4. In FIGS. 3A and 3B, two dummy openings 3 each having a shape similar to a shape of the opening 2 are arranged in the first direction X relative to the opening 2 in the region sandwiched between the two adjacent virtual lines 4. Even in this case, all of the distances between the dummy openings 3 and the virtual lines 4 in the second direction Y can be longer than the shortest distance of the distances between the opening 2 and the virtual lines 4. Such a configuration makes it possible to suppress film deposition of the vapor deposition material on the scribe line while suppressing distortion of the opening 2.

FIGS. 3C to 3F illustrate examples in which the plurality of openings 2 and the plurality of dummy openings 3 are provided in the region sandwiched between the two adjacent virtual lines 4. In FIG. 3C, each of the plurality of openings 2 has a polygonal shape, and two dummy openings 3 are arranged between the opening region W and the end of the vapor deposition mask (not illustrated, on right side in drawing). The dummy openings 3 each having a size smaller than a size of each of the dummy openings 3 arranged outside the opening region W are arranged in the opening region W.

In FIG. 3D, each of the plurality of openings 2 has a rectangular shape, and one dummy opening 3 is arranged between the opening region W and the end of the vapor deposition mask (not illustrated, on right side in drawing). The dummy openings 3 each having a size smaller than a size of the dummy opening 3 arranged outside the opening region W are arranged in the opening region W.

In FIG. 3E, the plurality of openings 2 has rectangular shapes different in size, and one dummy opening 3 is arranged between the opening region W and the end of the vapor deposition mask (not illustrated, on right side in drawing). The dummy openings 3 each having a size different from a size of the dummy opening 3 arranged outside the opening region W are arranged in the opening region W.

In FIG. 3F, two openings 2 each having a rectangular shape are arranged, and the dummy opening 3 is arranged side by side with the openings 2 in the first direction X between the openings 2 and the end of the vapor deposition mask (not illustrated, on right side in drawing). Two dummy openings 3 each having an elliptical shape and one dummy opening 3 having a rectangular shape are arranged at positions overlapping with the openings 2 in the second direction Y.

Even in the configurations illustrated in FIGS. 3C to 3F, all of the distances between the dummy openings 3 and the virtual lines 4 in the second direction Y can be longer than the shortest distance of the distances between the openings 2 and the virtual lines 4. Such a configuration makes it possible to suppress film deposition of the vapor deposition material on the scribe line while suppressing distortion of the openings 2.

As illustrated in FIGS. 2A to 2E and FIGS. 3A to 3F, the opening 2 and the dummy opening 3 adjacent to each other in the first direction X are desirably overlapped in the first direction X. A part A overlapping with a part B in a certain direction indicates that, in a case where the part A and the part B are projected to a surface perpendicular to the certain direction, projection charts thereof have portions overlapping with each other. In a case where the plurality of dummy openings 3 is arranged in the region sandwiched between two adjacent virtual lines, it is sufficient for any one of the dummy openings 3 to overlap with the adjacent opening 2 in the first direction, and it is unnecessary for all of the plurality of dummy openings 3 to overlap with the openings 2.

The openings 2 and the dummy openings 3 are not particularly specified as long as the openings 2 and the dummy openings 3 penetrate through the vapor deposition mask from a surface facing the substrate to a rear surface of the vapor deposition mask. Each of the openings 2 and the dummy openings 3 may be an opening perpendicular to the plane of the vapor deposition mask, or an opening in which a shape on the surface facing the vapor deposition mask and a shape on the rear surface of the vapor deposition mask are the same as or different from each other. The sizes of the openings may be equal to or different from each other. In a case where each of the openings 2 and the dummy openings 3 has the shape and the size different between on the surface of the vapor deposition mask facing the substrate and on the rear surface of the vapor deposition mask, the shape and the size in the present specification indicate the shape and the size on the surface of the vapor deposition mask facing the substrate.

The openings 2 are the effective openings for forming the organic EL elements, and the third openings are the dummy openings not used for forming the organic EL elements.

As described above, in the case where the plurality of virtual lines 4 is provided, the single opening 2 or the plurality of openings 2 may be arranged, but at least one opening 2 is preferably disposed in the region between the adjacent virtual lines 4. As illustrated in FIGS. 3C to 3F, in the first direction X and the second direction Y, the dummy opening 3 may be sandwiched between the openings 2, or the opening 2 may be sandwiched between the dummy openings 3. Alternatively, the dummy opening 3 and the opening 2 may be adjacent to each other.

When the vapor deposition mask is attached to a frame supporting the vapor deposition mask, even in a case of a tension mask strained with tensile force or a vapor deposition mask simply fixed by pins, screws, or the like, force may be applied in a direction distorting the openings in order to maintain constant planarity. The dummy openings 3 are arranged not only around the frame but also in a space between the pins/screws and the effective openings, which makes it possible to relax the force, and to vapor-deposit a desired pattern.

In a case where the dummy openings 3 are provided for another purpose, for example, the dummy openings 3 are provided as inspection regions for checking soundness of the manufacturing step. In the present exemplary embodiment, the dummy openings 3 are openings for forming vapor-deposited films not having a function for element formation, and purposes such as use application of the formed films are not particularly limited.

In the present exemplary embodiment, the example in which each of the openings 2 and the dummy openings 3 has a rectangular shape, a polygonal shape, or an elliptical shape is described, but the shape of each of the openings 2 and the dummy openings 3 is not particularly limited. For example, each of the openings 2 and the dummy openings 3 may have a polygonal shape such as a triangular shape, a quadrilateral shape, and pentagonal to dodecagonal shapes, a shape not including a corner, such as a circular shape or an elliptical shape, or a shape such as a semicircular shape.

In FIGS. 1A to 1C, as the examples of the shape of the vapor deposition mask 1, the quadrilateral shape and the circular shape are illustrated, but the shape of the vapor deposition mask 1 is not limited to these shapes. For example, the shape of the vapor deposition mask 1 may be a circular shape or a polygonal shape, or a shape including a notch or a protrusion fitted to a vapor deposition mask conveyance mechanism or a vapor deposition mask frame of a vapor deposition apparatus.

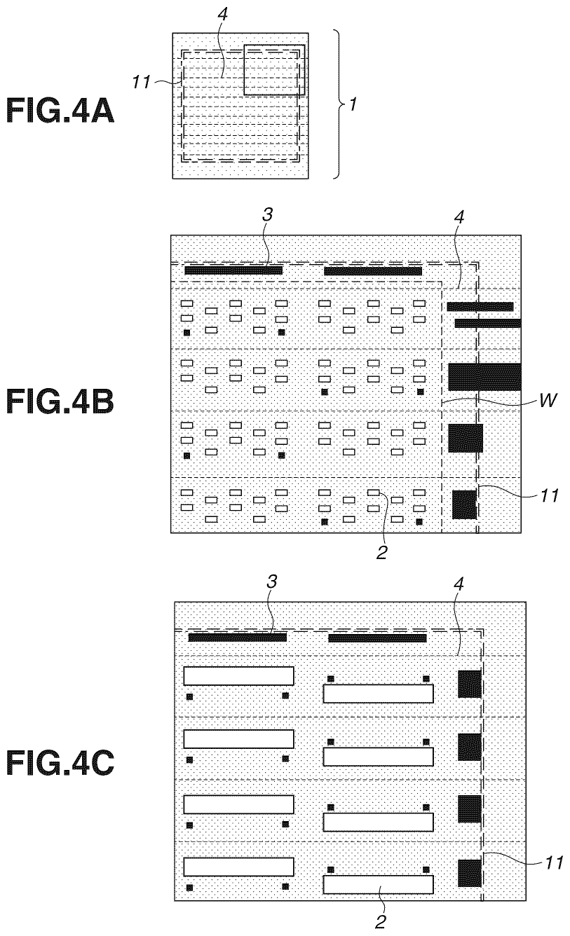

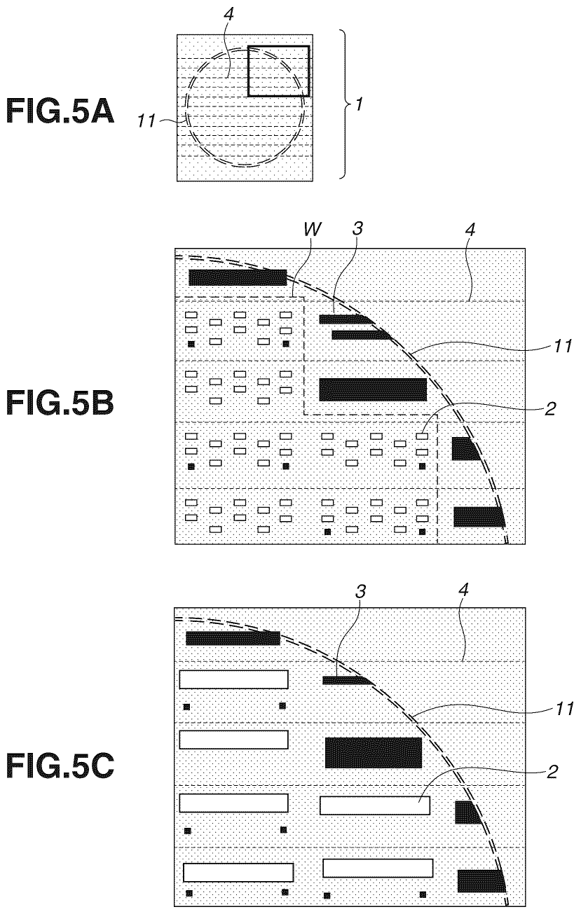

FIG. 4A is a schematic diagram illustrating an example of a configuration as viewed from the vapor deposition mask side in a case where the vapor deposition mask 1 according to the present exemplary embodiment faces the substrate having the quadrilateral shape. FIGS. 4B and 4C are enlarged views of a portion inside a thick line illustrated in FIG. 4A. FIG. 5A is a schematic diagram illustrating an example of a configuration as viewed from the vapor deposition mask side in a case where the vapor deposition mask 1 according to the present exemplary embodiment faces a circular substrate. FIGS. 5B and 5C are enlarged views of a portion inside a thick line illustrated in FIG. 5A.

As illustrated in the enlarged views, each of the dummy openings 3 provided outside the opening region W may have a shape along an end of a substrate 11 facing the vapor deposition mask 1 according to the present exemplary embodiment, or may have a different shape. For example, as illustrated in FIG. 4B and FIG. 5B, each of the dummy openings 3 may have a shape protruding from the end of the substrate 11, or as illustrated in FIG. 4C and FIG. 5C, each of the dummy openings 3 may have a shape having an edge aligned with the end of the substrate 11.

It is preferable that each of the dummy openings 3 have the shape along the end of the substrate 11 as illustrated in FIG. 4C and FIG. 5C because it is possible to reduce unnecessary film deposition of the vapor deposition material on the vapor deposition mask frame on which the vapor deposition mask 1 is installed and other portions inside a vapor deposition chamber.

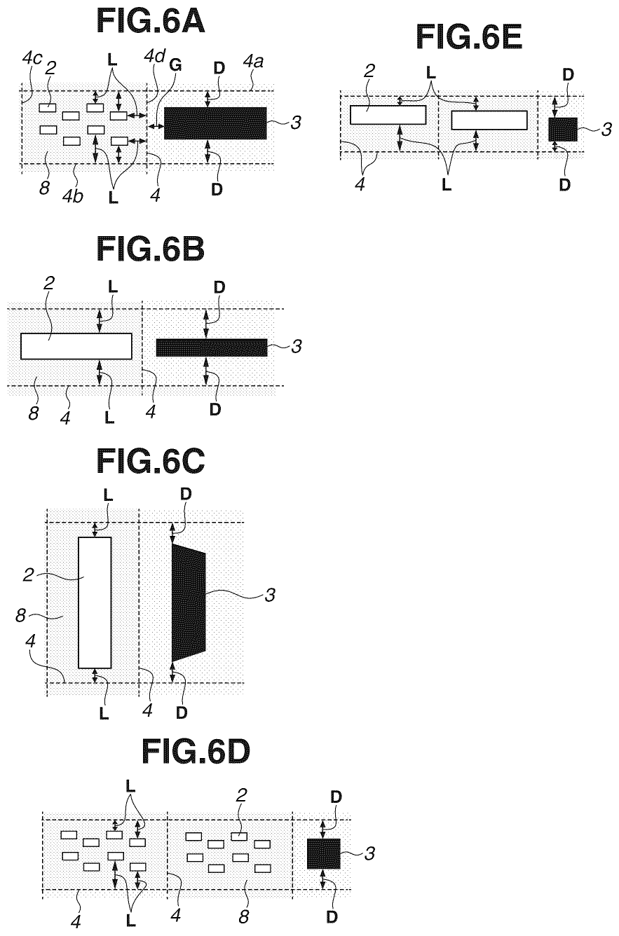

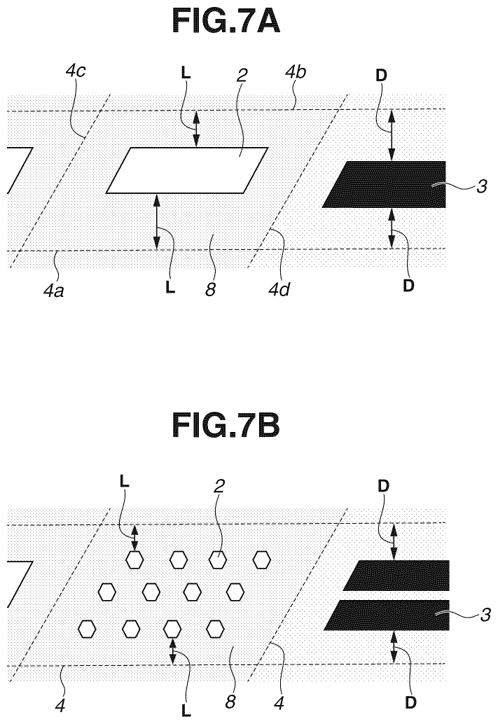

An arrangement of the openings 2 is described with reference to FIGS. 6A to 6E and FIGS. 7A and 7B. In FIG. 6A, the plurality of openings 2 is arranged between the virtual line 4a and the virtual line 4b that are two adjacent virtual lines 4. In FIGS. 6B and 6C, one opening 2 is arranged between the two adjacent virtual lines 4. In FIG. 6B, the dummy opening 3 is less in width in the second direction Y than the dummy opening 3 illustrated in FIG. 6A. In FIG. 6C, the opening 2 and the dummy opening 3 each have a shape in which long sides are parallel to the second direction Y and short sides are parallel to the first direction X, and the dummy opening 3 has a trapezoidal shape.

The vapor deposition mask 1 illustrated in each of FIGS. 6A to 6E has virtual lines 4 extending in the second direction Y perpendicular to the first direction X. For example, the vapor deposition mask 1 illustrated in FIG. 6A has a third virtual line 4c and a fourth virtual line 4d that are two adjacent virtual lines 4 extending in the second direction Y.

Likewise, the vapor deposition mask 1 illustrated in each of FIGS. 6B to 6E has the third virtual line 4c and the fourth virtual line 4d that are two adjacent virtual lines 4 extending in the second direction Y.

In the vapor deposition mask 1 illustrated in each of FIGS. 7A and 7B, the third virtual line 4c and the fourth virtual line 4d are parallel to each other and intersect the first direction X, but are not orthogonal to the first direction X.

One or a plurality of openings may be arranged in a region E surrounded by the first virtual line 4a, the second virtual line 4b, the third virtual line 4c, and the fourth virtual line 4d, but at least one opening 2 is preferably arranged.

Even in such a configuration of the vapor deposition mask 1 illustrated in each of FIGS. 6A to 6E and FIGS. 7A and 7B, the shortest distance of the distances between the openings 2 and the virtual lines 4 is shorter than all distances between the dummy openings 3 and the virtual lines 4 in the second direction Y. In this case, in the first direction X, the shortest distance of the distances between the openings 2 and the virtual lines 4 extending in the second direction Y is shorter than all distances between the dummy openings 3 and the virtual lines 4 extending in the second direction Y.

Accordingly, it is possible to suppress film deposition of the vapor deposition material on the scribe line while suppressing distortion of the openings 2.

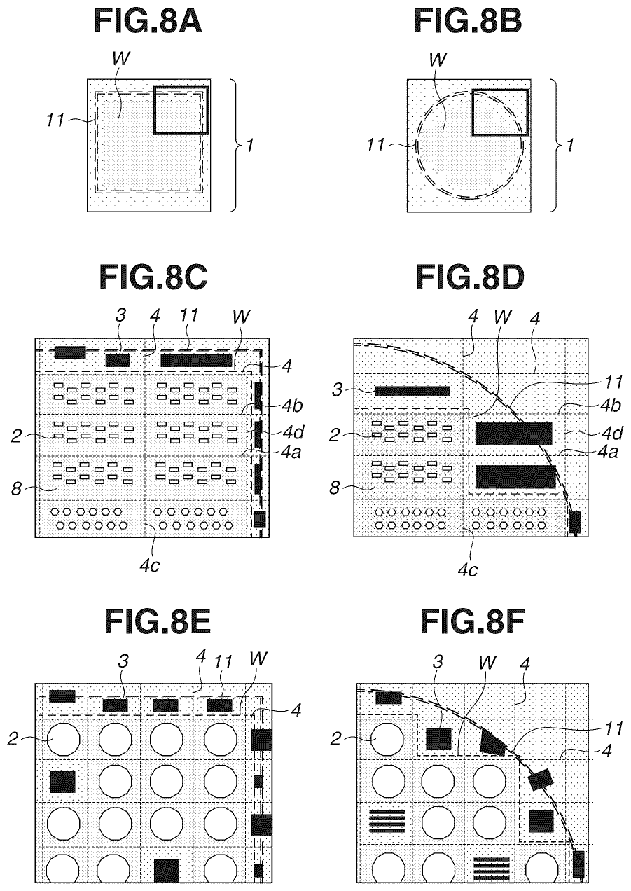

FIGS. 8A to 8F are schematic diagrams illustrating examples of a configuration as viewed from the vapor deposition mask side in a case where the vapor deposition mask 1 including the virtual lines 4 (virtual lines 4a and 4b) extending in the first direction X and the virtual lines 4 (virtual lines 4c and 4d) extending in the second direction Y faces the quadrilateral or circular substrate.

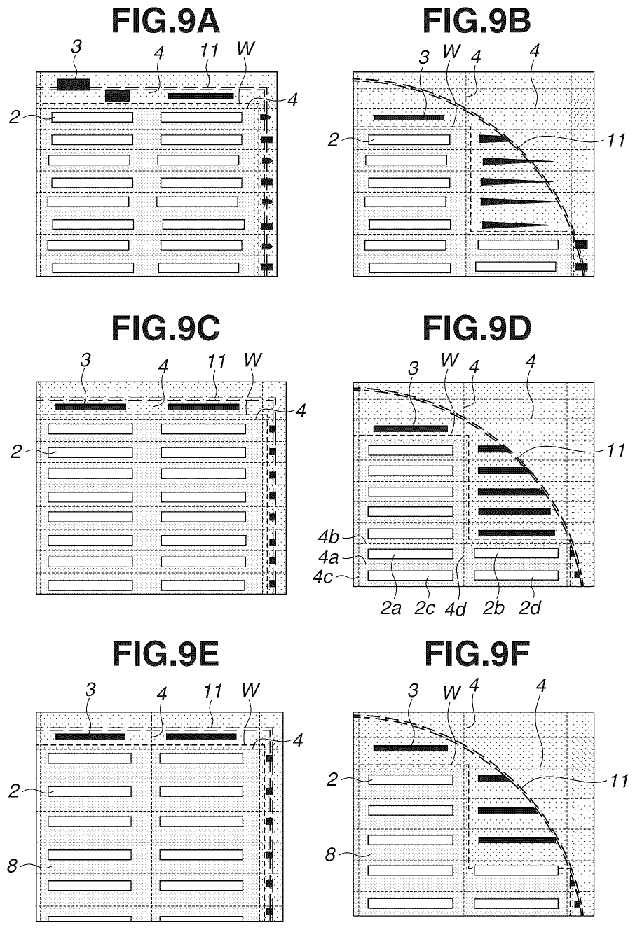

FIG. 8A is a schematic diagram illustrating an example of a configuration as viewed from the vapor deposition mask side in a case where the vapor deposition mask 1 according to the present exemplary embodiment faces the quadrilateral substrate. FIGS. 8C and 8E and FIGS. 9A, 9C, and 9E are enlarged views of a portion inside a thick line illustrated in FIG. 8A. FIG. 8B is a schematic diagram illustrating an example of a configuration as viewed from the vapor deposition mask side in a case where the vapor deposition mask 1 according to the present exemplary embodiment faces the circular substrate. FIGS. 8D and 8F and FIGS. 9B, 9D, and 9F are enlarged views of a portion inside a thick line illustrated in FIG. 8B.

As illustrated in the enlarged views, each of the dummy openings 3 provided outside the opening region W may have a shape along the end of the substrate 11 facing the vapor deposition mask 1 according to the present exemplary embodiment, or may have a different shape. For example, as illustrated in FIG. 8C to FIG. 9B, each of the dummy openings 3 may have a shape protruding from the end of the substrate 11, or as illustrated in FIGS. 9C to 9F, each of the dummy openings 3 may have a shape having an edge aligned with the end of the substrate 11.

It is preferable that each of the dummy openings 3 have the shape along the end of the substrate 11 as illustrated in FIGS. 9C to 9F because it is possible to reduce unnecessary film deposition of the vapor deposition material on the vapor deposition mask frame on which the vapor deposition mask 1 is installed and other portions inside the vapor deposition chamber.

The opening region W according to the present exemplary embodiment includes the plurality of openings. For example, in FIG. 9D, the opening region W includes the first opening 2a and the second opening 2b that are arranged along the virtual line 4 (first virtual line) extending in the first direction X. The opening region W includes a fourth opening 2c that is arranged adjacent to the first opening 2a with the first virtual line being arranged therebetween, and a fifth opening 2d that is arranged side by side with the fourth opening 2c in the first direction X. The fifth opening 2d is adjacent to the second opening 2b with the first virtual line being arranged therebetween. The dummy openings 3 (third openings) are arranged outside the opening region W. Even in such a configuration, any of the distances between the dummy openings 3 and the virtual lines 4 adjacent to the dummy openings 3 is longer than the shortest distance of the distances between the openings 2 and the virtual lines 4. Accordingly, it is possible to suppress film deposition of the vapor deposition material on the scribe line while suppressing distortion of the openings 2.

Each of the organic EL elements created using the vapor deposition mask 1 according to the present exemplary embodiment is an element including at least one organic compound layer between a first electrode and a second electrode. One of the first electrode and the second electrode is a positive electrode, and the other is a negative electrode. In each of the organic EL elements according to the present exemplary embodiment, the organic compound layer may be a single layer or a stacked body including a plurality of layers as long as the organic compound layer includes a light emission layer.

In a case where the organic compound layer is a stacked body including a plurality of layers, the organic compound layer may include, in addition to the light emission layer, a hole injection layer, a hole transport layer, an electron blocking layer, a hole/exciton blocking layer, an electron transport layer, and an electron injection layer. The light emission layer may be a single layer or a stacked body including a plurality of layers.

In a case where a plurality of light emission layers is provided, a charge generation layer may be provided between the light emission layers. The charge generation layer may be made of a compound lower in lowest unoccupied molecular orbital (LUMO) than the hole transport layer, and the LUMO of the charge generation layer may be lower than highest occupied molecular orbital (HOMO) of the hole transport layer. The molecular orbital energy of the organic compound layer may be molecular orbital energy of an organic compound having the largest weight ratio in the organic compound layer.

The HOMO and the LUMO closer to a vacuum level are expressed as “higher”. The LUMO of the charge generation layer being lower than the HOMO of the hole transport layer indicates that the LUMO of the charge generation layer is close to the vacuum level as compared with the HOMO of the hole transport layer.

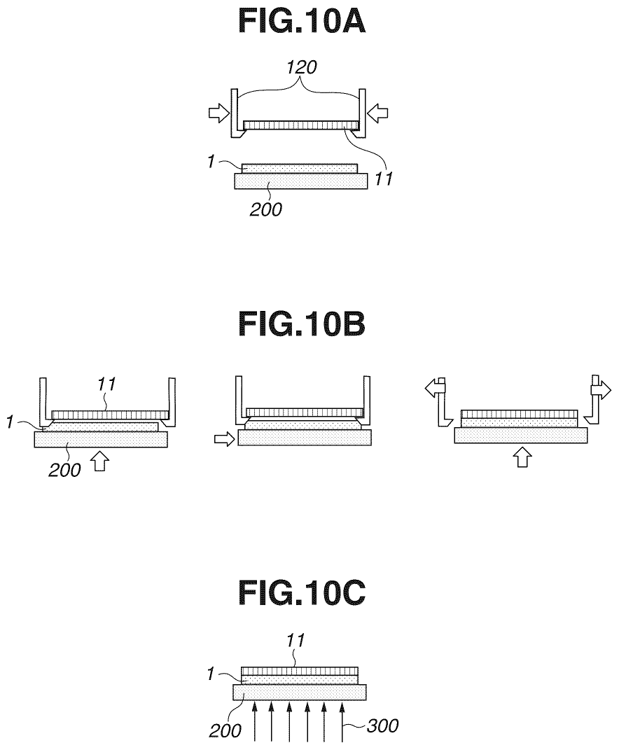

A vacuum deposition step using the vapor deposition mask 1 according to the present exemplary embodiment is described with reference to FIGS. 10A to 10C, but the present disclosure is not limited to the example. In the vapor deposition chamber, a desired vapor deposition pattern can be formed on the substrate 11 by, for example, the following configuration. A method of manufacturing an organic EL element includes a step of causing the vapor deposition mask according to the present exemplary embodiment and the substrate 11 to face each other, a step of aligning the substrate 11 and the vapor deposition mask, and a step of forming the desired pattern by vapor-depositing the vapor deposition material on the substrate through the openings of the vapor deposition mask 1. In the step of aligning the substrate 11 and the vapor deposition mask 1, the scribe lines provided on the substrate 11 and the respective virtual lines 4 of the vapor deposition mask 1 face each other.

As illustrated in FIG. 10A, the substrate 11 held by a substrate holding arm 120 and the vapor deposition mask 1 placed on a mask stage 200 are caused to face each other. As illustrated in FIG. 10B, the substrate 11 and the vapor deposition mask 1 are aligned by, for example, moving one or both of the substrate 11 and the vapor deposition mask 1. At this time, the virtual lines 4 are sets of positions on the vapor deposition mask 1 facing the scribe lines provided on the substrate 11. As illustrated in FIG. 10C, the desired pattern is formed on the substrate 11 by vapor-depositing a vapor deposition material 300 on the substrate 11 through the openings 2 (not illustrated) of the vapor deposition mask 1.

In the vapor deposition mask 1, the distances L between the openings 2 as the effective openings and the virtual lines 4 in the second direction Y are each set to a distance greater than or equal to a distance for which the vapor deposition material is not film-deposited on the scribe line even if predicted vapor deposition blur occurs in the vapor deposition step. The distances D between the dummy openings 3 (third openings) and the virtual lines 4 in the second direction Y are longer than the shortest distance L of the distances L between the openings 2 and the virtual lines 4 in the second direction Y. Accordingly, each of the third openings is separated in the second direction Y from the virtual lines 4 by a distance greater than the distance for which the vapor deposition material is not film-deposited on the scribe line during vapor deposition.

In the vapor deposition step, the shapes of the dummy openings 3 arranged outside the opening region W may be distorted, and vapor deposition blur caused by the vapor deposition material deposited through the dummy openings 3 may become greater than vapor deposition blur previously predicted relative to the openings 2 as the effective openings. However, when vapor deposition is performed using the vapor deposition mask 1 according to the present exemplary embodiment, for example, even if the shapes of the dummy openings 3 are distorted, it is possible to suppress adhesion (film deposition) of the vapor deposition material deposited through the dummy openings 3 to the scribe lines.

An organic EL element manufacturing apparatus is described using an example, but the present disclosure is not limited to the example. Each of the organic EL elements includes a plurality of functional layers. A vapor deposition apparatus as the manufacturing apparatus includes a number of vapor deposition chambers corresponding to the plurality of functional layers. The vapor deposition apparatus may include, in addition to the vapor deposition chambers, a plurality of process chambers such as a preparation chamber, a pretreatment chamber, a conveyance chamber, a relay chamber, and a substrate stock chamber.

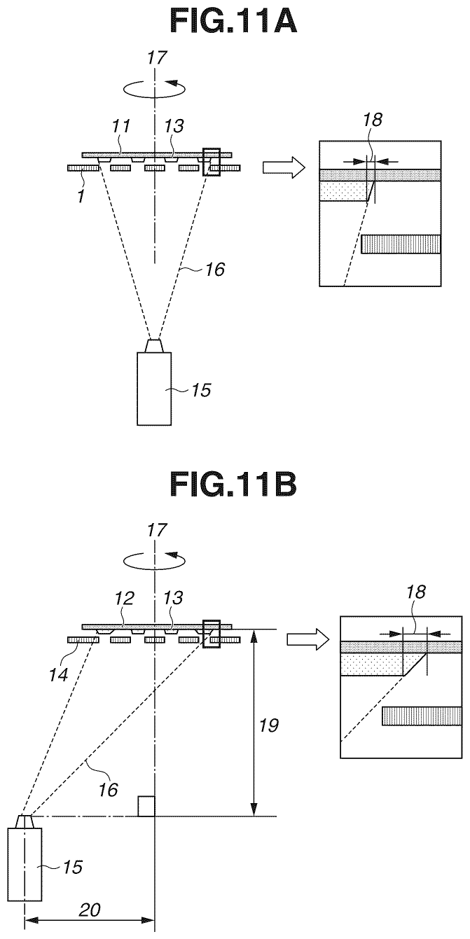

FIG. 11A is a schematic diagram illustrating an inside of a vapor deposition chamber in which the substrate and the vapor deposition mask facing each other are installed just above a vapor deposition source, and film formation of one layer is assumed. On the other hand, FIG. 11B is a schematic diagram illustrating an inside of a vapor deposition chamber in a case where it is assumed that a plurality of layers is continuously formed in one vapor deposition chamber. In the drawing, only one crucible 15 is illustrated for description, but a plurality of crucibles 15 may be provided. As compared with FIG. 11A, in the vapor deposition chamber illustrated in FIG. 11B, vapor deposition blur 18 illustrated in an enlarged view of a portion surrounded by a thick line is large. This is because, as compared with the vapor deposition chamber illustrated in FIG. 11A, in the vapor deposition chamber illustrated in FIG. 11B, an incident angle formed by the substrate 11 and a dotted line 16 extending from the vapor deposition source to the opening on the outermost peripheral part is small. A width of the vapor deposition blur 18 depends on distance relationship described below.
A. Distance between substrate 11 and vapor deposition mask 1
B. TS distance 19 as perpendicular distance from vapor deposition source to plane of substrate
C. OFFSET 20 as distance between center of crucible opening and point where perpendicular line from center of substrate to crucible opening surface intersects with plane of crucible opening
   [Case where A and B are Fixed]

In FIG. 11B, the incident angle formed by the substrate 11 and the dotted line 16 extending from the vapor deposition source to the opening on the outermost peripheral part is increased as the crucible 15 moves in a horizontal direction, namely, as C becomes shorter. Thus, the width of the vapor deposition blur 18 is reduced. For this reason, in a case where A and B are fixed, C can be short because it is possible to suppress vapor deposition blur and to reduce film deposition on the scribe line.

[Case where a and C are Fixed]

In FIG. 11B, the incident angle formed by the substrate 11 and the dotted line 16 extending from the vapor deposition source to the opening on the outermost peripheral part is increased as the crucible 15 moves in a vertical direction, namely, as B becomes longer. Thus, the width of the vapor deposition blur 18 is reduced. For this reason, in a case where A and C are fixed, B can be long because it is possible to suppress vapor deposition blur and to reduce film deposition on the scribe line.

[Case where B and C are Fixed]

In FIG. 11B, the incident angle formed by the substrate 11 and the dotted line 16 extending from the vapor deposition source to the opening on the outermost peripheral part is increased as A becomes shorter. Thus, the width of the vapor deposition blur 18 is reduced. For this reason, in a case where B and C are fixed, A can be short because it is possible to suppress vapor deposition and to reduce film deposition on the scribe line.

In a case where two or more of A, B, and C are varied, the width of the vapor deposition blur 18 is increased or reduced depending on a variation width.

Examples are described below. The present invention is not limited to the Examples. The terms used in Examples are the same as the terms used in the exemplary embodiment unless otherwise particularly noted, and repetitive description is omitted.

Example 1 is described. The vapor deposition mask 1 illustrated in FIG. 2A according to the present exemplary embodiment and a substrate were caused to face each other, and 20 nm of a co-deposited film of Ag/Mg was formed at a ratio of Ag:Mg=1:1 by using a vacuum deposition apparatus. A state of vapor deposition blur of the vapor-deposited film was observed using a light microscope. Table 1 illustrates the distance between the vapor deposition mask and the substrate, the TS distance, and OFFSET.

TABLE 1

| | | |
|---|---|---|
| Distance between Substrate and Vapor Deposition Mask | ≤30 | μm |
| TS Distance | 530 | mm |
| OFFSET | 210 | mm |

Example 2 is described. The vapor deposition mask illustrated in FIG. 2C according to the present exemplary embodiment and a substrate were caused to face each other, and 40 nm of a film of tris(8-hydroxyquinolinato)aluminum (hereinafter, Alq3) was formed using a vacuum deposition apparatus. A state of vapor deposition blur of the vapor-deposited film was observed using a light microscope. Table 2 illustrates the distance between the vapor deposition mask and the substrate, the TS distance, and OFFSET.

TABLE 2

| | | |
|---|---|---|
| Distance between Substrate and Vapor Deposition Mask | ≤30 | μm |
| TS Distance | 430 | mm |
| OFFSET | 210 | mm |

Examples 3 to 8 are described. A co-deposited film or a single film was formed in the same manner as Examples 1 and 2 except that a vapor deposition mask was changed, and a state of vapor deposition blur was observed using a light microscope. Table 3 illustrates vapor deposition masks.

TABLE 3

| Example | Vapor Deposition Mask |
|---|---|
| Example 3 | FIG. 3B |
| Example 4 | FIG. 3D |
| Example 5 | FIG. 6A |
| Example 6 | FIG. 6C |
| Example 7 | FIG. 6E |
| Example 8 | FIG. 7B |

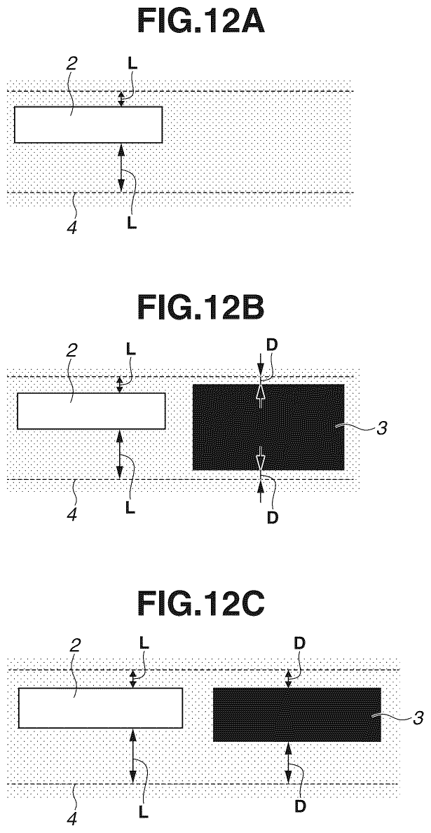

Comparative Examples 1 to 3 are described. A co-deposited film or a single film was formed in the same manner as Example 1 or 2 except that vapor deposition masks illustrated in FIGS. 12A to 12C are used, and a state of vapor deposition blur was observed using a light microscope.

The vapor deposition mask illustrated in FIG. 12A does not include the dummy opening, and includes only the opening 2 as the effective opening. The vapor deposition mask illustrated in FIG. 12B includes the dummy opening 3 between the opening 2 and the end of the vapor deposition mask. In FIG. 12B, in the second direction Y, the distances between the opening 2 and the virtual lines 4 are greater than the distances D between the dummy opening 3 and the virtual lines 4. The vapor deposition mask illustrated in FIG. 12C is similar to the vapor deposition mask illustrated in FIG. 12B in that the dummy opening 3 is provided between the opening 2 and the end of the vapor deposition mask. The vapor deposition mask illustrated in FIG. 12C is different from the vapor deposition masks in Examples 1 to 8 and Comparative Example 2 in that, in the second direction Y, the distances L between the opening 2 and the virtual lines 4 are equal to the respective corresponding distances D between the dummy opening 3 and the virtual lines 4.

Examples 1 to 8 and Comparative Examples 1 to 3 were evaluated in terms of the following points. As a first evaluation, presence/absence of vapor deposition blur at the opening 2 positioned on the outermost side in the opening region (opening 2 adjacent to dummy opening 3 in Examples 1 to 8 and Comparative Examples 2 and 3) was evaluated. As a second evaluation, to evaluate presence/absence of film deposition on the scribe line, a deposition position of the vapor deposition material deposited through the dummy opening 3 was observed. In Comparative Example 1 including no dummy opening, a deposition position of the vapor deposition material deposited through the opening 2 adjacent to the dummy opening was observed.

Table 4 illustrates shapes of the vapor deposition masks, deposited materials, the TS distance, and results of the first and second evaluations.

TABLE 4

| | Opening | | | | | | |
|---|---|---|---|---|---|---|---|
| | | | Dummy | | TS Distance | Evaluation | |
| | Shape | | Opening | Material | [mm] | 1 | 2 |
| Example 1 | FIG. 2A | | Present | Ag/Mg | 530 | Absent | Absent |
| Example 2 | FIG. 2C | | Present | Alq3 | 430 | Absent | Absent |
| Example 3 | FIG. 3B | | Present | Alq3 | 430 | Absent | Absent |
| Example 4 | FIG. 3D | | Present | Ag/Mg | 530 | Absent | Absent |
| Example 5 | FIG. 6A | | Present | Alq3 | 430 | Absent | Absent |
| Example 6 | FIG. 6C | | Present | Ag/Mg | 530 | Absent | Absent |
| Example 7 | FIG. 6E | | Present | Ag/Mg | 530 | Absent | Absent |
| Example 8 | FIG. 7B | | Present | Ag/Mg | 530 | Absent | Absent |
| Comparative | FIG. 12A | | Absent | Alq3 | 430 | Present | Present |
| Example 1 | | | | | | | |
| Comparative | FIG. 12B | L > 1 | Present | Ag/Mg | 530 | Absent | Present |
| Example 2 | | | | | | | |
| Comparative | FIG. 12C | L = 1 | Present | Ag/Mg | 530 | Absent | Present |
| Example 3 | | | | | | | |

In the present disclosure, as a method of determining the first evaluation, a case where the vapor deposition blur was extended by 20 μm or more on outside of an end part of an effective film deposition region (predicted deposition region) on the substrate was evaluated as “present”. As a method of determining the second evaluation, presence/absence of the vapor deposition material actually deposited on the scribe line was evaluated.

As illustrated in Table 4, in cases of using the vapor deposition masks according to Examples 1 to 8, it was confirmed that the vapor deposition blur was less than 20 μm even at the opening 2 on the outermost side at which vapor deposition blur was predicted to be the largest in the opening region W. In contrast, in Comparative Example 1 not including the dummy opening 3, 20 μm or more of vapor deposition blur was observed.

In the cases of using the vapor deposition masks according to Examples 1 to 8, film deposition of the vapor deposition material on the scribe line was not observed. In contrast, in Comparative Example 1 not including the dummy opening 3 and in Comparative Examples 2 and 3 in which the distances between the dummy opening 3 and the virtual lines 4 were less than or equal to the distances L between the opening 2 and the virtual lines 4, film deposition of the vapor deposition material on the scribe line was observed.

It was confirmed from Examples that performing vapor deposition of the vapor deposition material by using the vapor deposition mask according to the present exemplary embodiment made it possible to suppress vapor deposition blur caused by deviation in rigidity in the plane of the vapor deposition mask. It was confirmed that performing vapor deposition of the vapor deposition material by using the vapor deposition mask according to the present exemplary embodiment made it possible to reduce film deposition of the vapor deposition material on the scribe line.

With the above-described configuration, it is possible to provide the vapor deposition mask that can reduce film deposition of the vapor deposition material on the scribe line that is a dicing position of the substrate.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-129372, filed Aug. 8, 2023, which is hereby incorporated by reference herein in its entirety.

What is claimed is:

1. A vapor deposition mask comprising:
an opening region including a first opening and a second opening; and
a third opening and a fourth opening arranged outside the opening region,
wherein the first opening and the second opening are arranged along a first virtual line extending in a first direction,
wherein the third opening is arranged between the first opening and a first end of the vapor deposition mask in the first direction,
wherein the fourth opening is arranged between the first opening and a second end of the vapor deposition mask in a second direction orthogonal to the first direction, and
wherein, in the second direction, a distance between the first opening and the first virtual line is shorter than a distance between the third opening and the first virtual line.

2. The vapor deposition mask according to claim 1, wherein the first opening includes a first side parallel to the first direction, and a second side parallel to the second direction orthogonal to the first direction.

3. The vapor deposition mask according to claim 1,
wherein the opening region includes a fifth opening, and
wherein the fifth opening is arranged adjacent to the first opening with the first virtual line being arranged therebetween.

4. The vapor deposition mask according to claim 3, wherein the fifth opening is arranged at a position overlapping with the first opening in the second direction.

5. The vapor deposition mask according to claim 3,
wherein the opening region includes a sixth opening adjacent to the fifth opening in the first direction, and
wherein the sixth opening is adjacent to the second opening with the first virtual line being arranged therebetween.

6. The vapor deposition mask according to claim 1, wherein the third opening is positioned between the first virtual line and a second virtual line, the second virtual line being adjacent to the first opening on a side of the first opening opposite to the first virtual line and being parallel to the first virtual line.

7. The vapor deposition mask according to claim 1, wherein a shorter distance of (i) a distance between the first opening and the first virtual line and (ii) a distance between the first opening and a second virtual line, is shorter than a distance between the third opening and the second virtual line, in the second direction, the second virtual line being adjacent to the first opening on a side of the first opening opposite to the first virtual line and being parallel to the first virtual line.

8. The vapor deposition mask according to claim 6, wherein the second opening is positioned between the first virtual line and the second virtual line.

9. The vapor deposition mask according to claim 1,
wherein the opening region includes a plurality of openings between the first virtual line and a second virtual line, the second virtual line being adjacent to the first opening on a side of the first opening opposite to the first virtual line and being parallel to the first virtual line, and
wherein, in the second direction, a shorter distance of a distance between the third opening and the first virtual line and a distance between the third opening and the second virtual line is longer than a shortest distance of distances between the plurality of openings and the first virtual line and is longer than a shortest distance of distances between the plurality of openings and the second virtual line.

10. The vapor deposition mask according to claim 1, wherein the first opening and the second opening are effective openings, and the third opening is a dummy opening.

11. The vapor deposition mask according to claim 1,
wherein the first opening and the third opening are arranged along a second virtual line that passes between the first opening and the third opening and extends in the second direction, and
wherein, in the first direction, a distance between the first opening and the second virtual line is shorter than a distance between the third opening and the second virtual line.

12. The vapor deposition mask according to claim 1, wherein, in a dicing step of cutting off a substrate on which a substance is vapor-deposited using the vapor deposition mask, the first virtual line is a line facing a dicing line.

13. A method of manufacturing an organic electroluminescent (EL) element, the method comprising:
causing a vapor deposition mask and a substrate to face each other;
aligning the substrate and the vapor deposition mask; and
forming a pattern by vapor-depositing a vapor deposition material on the substrate through openings of the vapor deposition mask,
wherein the vapor deposition mask includes an opening region including a first opening and a second opening, and a third opening and a fourth opening arranged outside the opening region,
wherein the first opening and the second opening are arranged along a first virtual line extending in a first direction,
wherein the third opening is arranged between the first opening and a first end of the vapor deposition mask in the first direction,
wherein the fourth opening is arranged between the first opening and a second end of the vapor deposition mask in a second direction orthogonal to the first direction,
wherein, in the second direction, a distance between the first opening and the first virtual line is shorter than a distance between the third opening and the first virtual line, and
wherein, in the aligning, a position of a scribe line on the substrate and the first virtual line of the vapor deposition mask face each other.
